(19) United States
(12) Patent Application Publication
(10) Pub. No.: US 2026/0221769 A1
(43) Pub. Date: Jul. 30, 2026

(54) BALANCING DEVICE AND METHOD FOR BALANCING AN UNGROUNDED POWER SUPPLY SYSTEM AND ENHANCED INSULATION MONITORING DEVICE

(71) Applicant: Bender GmbH & Co. KG, Gruenberg (DE)

(72) Inventor: Julian Reitz, Gruenberg (DE)

(21) Appl. No.: 19/444,916

(22) Filed: Jan. 9, 2026

(30) Foreign Application Priority Data
Jan. 24, 2025 (DE) 10 2025 102 561.4

(51) Int. Cl. H02J 3/001; G01R 31/08

(52) U.S. Cl. CPC H02J 3/001; G01R 31/08

(57) ABSTRACT

A balancing device and method for balancing an ungrounded power supply system are disclosed. The balancing device is switched multipolarly between the corresponding active conductors and ground potential and comprises a voltage measuring device for each active conductor for detecting a corresponding conductor-to-ground voltage, a microcontroller which evaluates the conductor-to-ground voltages, a PFC controller for each active conductor, the PFC controller reproducing a control impedance in such a manner that a voltage balance is set between the active conductors, and further comprises an intermediate circuit which stores energy converted in the control impedances and a converter which outputs the energy stored in the intermediate circuit to the power supply system.

This application claims the benefit of German patent application no. 10 2025 102 561.4, filed January 24, 2025, the disclosure of which is incorporated herein by reference.

### TECHNICAL FIELD

The invention relates to a balancing device and a method for balancing an ungrounded power supply system having at least two active conductors, as well as to an enhanced insulation monitoring device having the balancing device according to the invention.

### BACKGROUND

When there are increased requirements for the operational, fire, and touch safety of electrical systems, an ungrounded power supply system is used, which is also referred to as an isolated network (French: "Isolé Terre"—IT) or an IT power supply system. In this type of power supply system, the active parts of the power supply system are isolated from the ground potential—to ground. The exposed conductive parts of the connected electrical consumers are grounded individually or collectively. The advantage of these networks is that, in the event of a first insulation fault, the operability of the connected electrical consumers is not impaired and operation can therefore continue despite the faulty condition of the insulation, as no closed circuit can form due to the ideally infinitely large electrical resistance (insulation resistance) between the corresponding active conductor of the network and ground potential.

To ensure electrical safety in ungrounded power supply systems, insulation monitoring devices (IMDs) are used in accordance with the IEC 61557-8 standard. These are capable of detecting and reporting critical system conditions, such as insufficient insulation levels or excessive ground capacity values. If necessary, a faulty branch is also shut down after an alarm message from the IMD.

Similarly, the balance of the line voltage in relation to the ground potential (conductor-to-ground voltage) can be used as a monitoring and signaling parameter. The balance of the conductor-to-ground voltages plays a prominent role alongside insulation resistance. According to the equation E = ½CU², the amount of energy stored in a (ground) leakage capacitance Cₑ increases quadratically with the applied voltage. If a complete voltage unbalance of the active conductors to ground is present at a constant operating voltage, the total amount of energy in the capacitances doubles. In conjunction with a simultaneous doubling of the conductor-to-ground voltage, this can pose a significantly increased risk to people and property when in contact with active conductors.

In order to keep the energy stored in the system in check, it is possible to reduce the leakage capacitances or to dimension them according to a worst-case scenario. However, depending on the size of the power supply system, this is not always possible. The problem of increased energy in capacitances is particularly relevant in the case of unbalanced conductor-to-ground voltages in ungrounded DC networks. Here, even high-impedance unbalances in the insulation levels of the active conductors to ground can lead to significant voltage shifts and associated increases in energy. In alternating current networks (AC networks), capacitances not only act as storage devices, but also as reactances. In many cases, especially in extensive industrial networks, the reactance of the leakage impedance is lower than the effective resistance. Thus, even an unbalanced arrangement of ground leakage capacitances can lead to relevant voltage shifts and thus to dangerous voltage surges.

In the event of a voltage unbalance in the AC network, the alternating voltage is the reason why the voltage-dependent load on the insulation material and the EMC protection circuits is of greater importance than the stored energy. Such components experience greater one-sided wear in the event of permanent voltage unbalances and their service life may be impaired.

Limiting the ground leakage capacitance is advantageous in both AC and DC networks, but is not always technically feasible.

An alternative and, due to the quadratic dependence, significantly more efficient method is active or passive balancing of the conductor-to-ground voltages.

Regardless of the detailed design, balancing usually involves energy consumption. This means that either energy is extracted on the side of the voltage increase, for example by means of ohmic resistances, and converted into heat, or energy is supplied in the form of a power source on the other side. Particularly in ungrounded AC networks with low leakage impedances, reactive power up to the kVA range may be required to achieve balancing.

An active method for voltage balancing with a neutral energy balance is the object of the invention described here.

According to the state of the art, the energy limitation of ground leakage capacitances in ungrounded power networks is achieved by application-specific specifications for the size of the permissible capacitance value. However, due to physical system properties, such as in PV systems, it is often not possible to impose any limitations.

It is also known that the conductor-to-ground voltage can be actively or passively balanced. A passive solution for this is a balanced voltage divider with ground potential in the center tap. Since these resistances, which remain permanently in the system, cannot be designed with sufficiently low resistance, this method is only a limited solution for unbalanced reductions in the insulation resistance. Well-known IMDs already fulfill this requirement due to their technical design with a balanced network coupling.

Active methods can evaluate the voltage unbalance and react appropriately.

Patent application document DE 102020006919 A1 describes such a method for determining an unbalanced load, with discrete resistance values being switched on or off between the active conductors and ground in order to compensate any voltage unbalances.

Active correction of an unbalanced load is also conceivable with voltage and power source circuits. Such a design within an enhanced insulation monitoring device is shown in patent application document WO 2023/007253 A1.

Patent specification DE 102018116055 B3 further describes a method and insulation monitor for resistance-adaptive insulation monitoring. A classic 3-voltmeter method is described, in which two operating points are observed. However, no discrete resistances are switched here; instead, a combination of a semiconductor switch and a resistance is modulated into a coupling resistance which remains constant over a certain integration time.

Patent application document DE 102020211760 A1 shows an arrangement of balancing resistances which are also used to discharge safety capacitors.

All of the aforementioned methods relate to ungrounded DC power supply systems. For ungrounded AC power supply systems, no methods or devices for balancing are known from the state of the art, in particular no measures which achieve balancing with a neutral energy balance.

### SUMMARY

The object of the invention at hand is therefore to design an electric switching device and a method by means of both of which the conductor-to-ground voltages are balanced as neutral in energy as possible in an ungrounded power supply system, in particular in an ungrounded AC power supply system, while also minimizing power loss.

This object is attained by a balancing device which is switched multipolarly between the corresponding active conductors and ground potential and has the features of claim 1.

The balancing device comprises a voltage measuring device which detects the corresponding conductor-to-ground voltage occurring at each active conductor to ground. A microcontroller evaluates the measured conductor-to-ground voltages and controls a PFC controller (power factor correction) installed for each active conductor, the conductor-to-ground voltages required to achieve balance being specified by the microcontroller as target values. The corresponding PFC controller controls the current consumption in such a manner that a control impedance is individually reproduced for each active conductor, the magnitude of this control impedance leading to the desired balancing of the conductor-to-ground voltages through the provision of reactive power. The balancing device also has an intermediate circuit to store the energy converted in the control impedances and a converter which delivers the energy stored in the intermediate circuit to the power supply system at a frequency adapted to the latter.

The balancing device is thus able to counteract the voltage surge of a conductor-to-ground voltage with a load in the form of a control impedance. In contrast to conventional methods for voltage balancing using (controllable) balancing resistances, the energy converted in the reproduced control impedance is not converted into heat (power loss), but is fed back into the power supply system as electrical energy between the active conductors.

The balancing device shown is designed in such a manner that a largely neutral energy balance is achieved in relation to the ungrounded power supply system to be balanced, i.e., neither energy is extracted and thermally utilized, nor does energy have to be supplied to fulfill the balancing task.

In a further design, the balancing device has a data circuit between the balancing device and an insulation monitoring device, information on the set control impedances being transferred to the insulation monitoring device via the data circuit.

The balancing device introduces control impedances into the power supply system, which are measured and displayed by an independent IMD. This would inevitably lead to false interpretations of the system status, for which reason the IMD display value is corrected. For this purpose, information on the set control impedances is transmitted to the IMD from the balancing device via the data circuit and calculated using known current-voltage relationships (parallel circuit of resistances).

The object of the invention is further attained by an enhanced insulation monitoring device which integrates the balancing device according to the invention and forms a structural unit with the balancing device.

An insulation monitoring device, which is enhanced in this manner and is primarily standard-compliant, thus performs the function of balancing the monitored ungrounded power supply system in addition to insulation monitoring. Electrical (e.g., power supply) and structural (e.g., casing) resources are used jointly and cost-efficiently in an advantageous manner.

The balancing device described above is based on the implementation of a method according to the invention. In this respect, the aforementioned technical effects are also reflected in the advantages of the method features.

In particular, the method is characterized by electrically almost loss-free balancing.

Furthermore, the balancing device can be used to test the operability of the insulation monitoring device.

Users can use balancing devices to supply (control) impedances to the power supply system and thus simulate a wide variety of system scenarios and the response of the insulation monitoring devices.

It is also possible to use the balancing device to generate common-mode currents, which are important for fault location using insulation fault location systems (IFLS) in ungrounded power supply systems.

### BRIEF DESCRIPTION OF DRAWINGS

Further advantageous design features are derived from the following description and the drawings, which detail a preferred embodiment of the invention by means of examples.

FIG. 1: shows an ungrounded single-phase power supply system having a balancing device according to the invention.

FIG. 2: shows the balancing device according to the invention in a functional view

FIG. 3: shows the ungrounded single-phase power supply system having the balancing device according to the invention and a data circuit to an insulation monitoring device.

### DETAILED DESCRIPTION

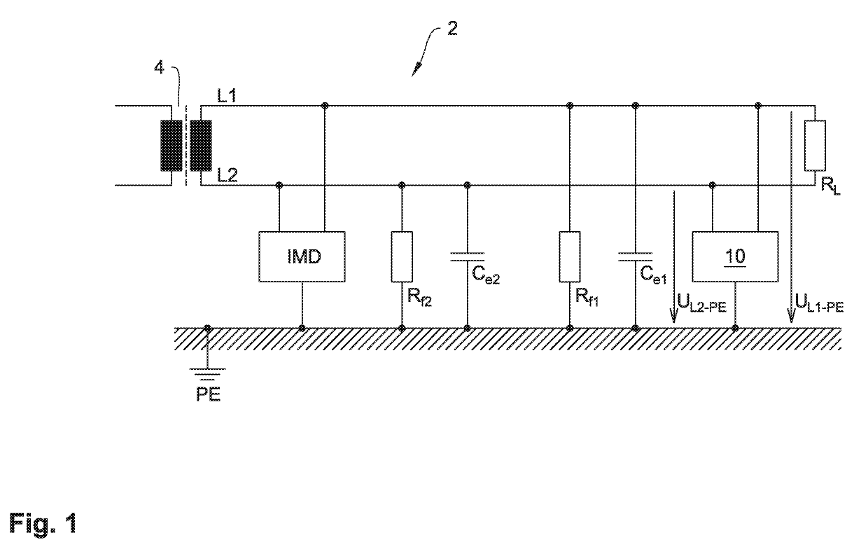

FIG. 1 shows an ungrounded single-phase power supply system 2 having a balancing device 10 according to the invention.

The power supply system 2 is exemplarily designed as a single-phase AC network having the active conductors L1, L2 and is fed by the isolating transformer 4.

Insulation resistances R_{f1}, R_{f2} and leakage capacitances Cₑ₁ and Cₑ₂ result in complex leakage impedances to ground (ground potential PE). A load resistance R_{L} is connected to the power supply system 2 as a consumer.

A balancing device 10 according to the invention is connected multipolarly between the corresponding active conductors L1, L2 and ground potential PE.

The total insulation resistance, which results here from the parallel circuit of the insulation resistances R_{f1}, R_{f2}, is determined by an insulation monitoring device IMD, which is also connected multipolarly between the corresponding active conductors L1, L2 and ground potential PE.

The power supply system 2 and the (non-enhanced) insulation monitoring device IMD represent an application environment for the present invention and are not part of the invention.

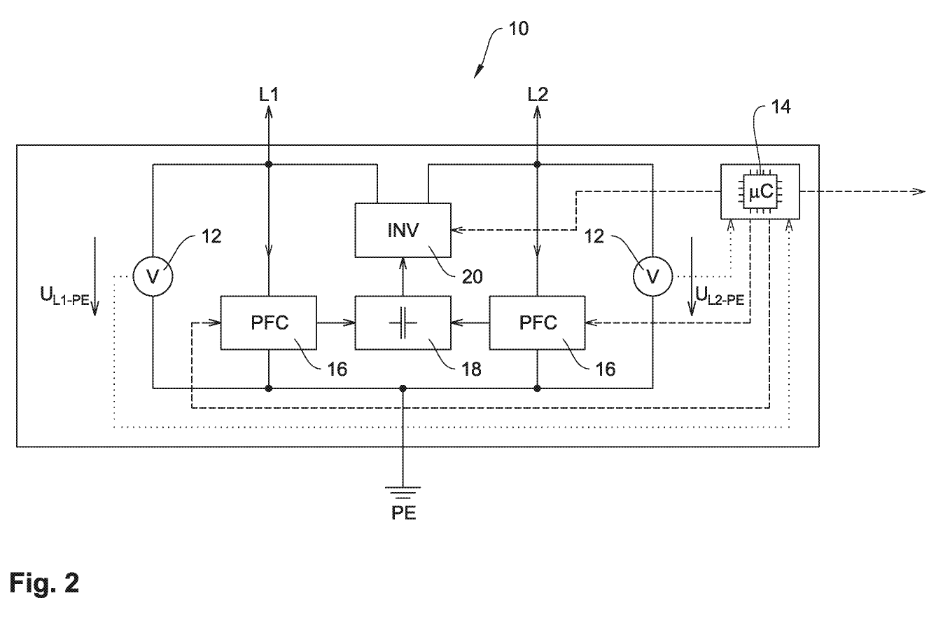

FIG. 2 shows the balancing device 10 according to the invention as a functional block diagram.

Conductor-to-ground voltages U_{L1-PE} and U_{L2-PE} are detected individually for each active conductor L1, L2 using voltage measuring devices 12 and fed to a microcontroller 14 for evaluation. Using the corresponding conductor-to-ground voltages U_{L1-PE}, U_{L2-PE} as target values, the microcontroller 14 controls a PFC controller 16 installed for each active conductor L1, L2. The PFC controllers 16 act as final controlling elements in a control loop and form the core element of the balancing device 10.

The PFC controllers 16, which are known from the field of power supply units, each function as an energy sink and map the control impedances required for balancing. PFC controllers 16 are active power electronic circuit groups which are used in particular for consumers having non-linear power consumption. In this context, PFC controllers 16 control the current consumption in such a manner that ohmic behavior with sinusoidal current consumption is established at sinusoidal voltage. In principle, a PFC controller 16 can therefore be regarded as a circuit group for the controlled provision of a control impedance. This behavior is necessary here in order to reproduced (control) impedances from effective resistance and reactance.

An intermediate circuit 18 absorbs the energy in the case of effective resistance or makes it available for use by the PFC controllers 16 as reactance.

A converter 20 transfers the energy from the intermediate circuit 18 to the power supply system 2.

If necessary, energy can also be fed from the converter into the intermediate circuit.

All planned power electronic assemblies can be considered virtually loss-free.

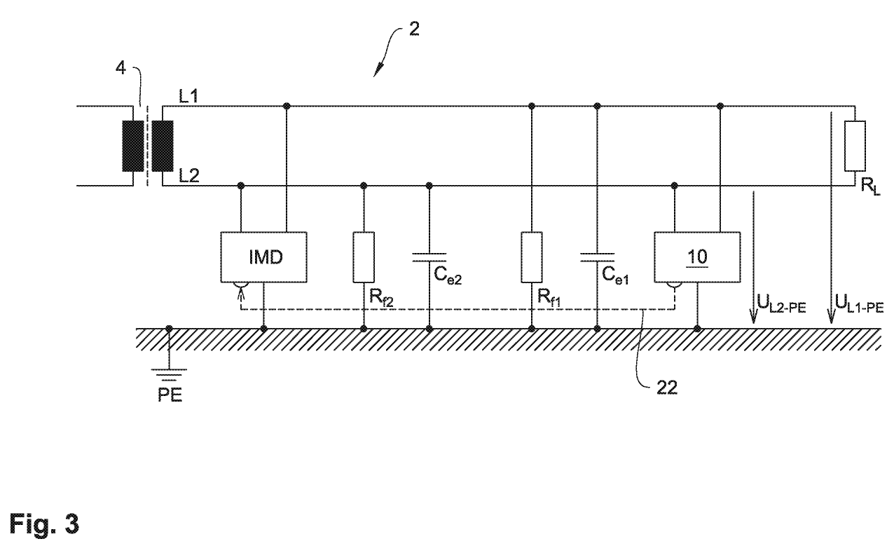

FIG. 3 supplements FIG. 1 by showing the ungrounded single-phase power supply system 2 having the balancing device 10 according to the invention and a data circuit 22 to the insulation monitoring device IMD.

Via the data circuit 22, the insulation monitoring device IMD obtains information on the control impedances which are introduced by the balancing device 10 in a conductor-specific manner. Since these control impedances influence the measurement result of the insulation monitoring device

IMD, they are taken into account in the insulation monitoring device IMD when determining the insulation resistance. This enables active and situational balancing without the insulation monitoring device IMD displaying erroneous measurement results.

In principle, a three-phase balancing device 10 corresponding to the balancing device of the invention and coupled in a three-phase configuration is also possible for a three-phase AC power supply system.

The balancing device 10 can also be used in both ungrounded AC and DC power supply systems 2.

1. A balancing device (10) for balancing an ungrounded power supply system (2) having at least two active conductors (L1, L2), the balancing device (10) being switched multipolarly between the corresponding active conductors and ground potential (PE), the balancing device (10) comprising a voltage measuring device (12) for detecting a corresponding conductor-to-ground voltage (U_{L1-PE} U_{L2-PE}) in the corresponding active conductor (L1, L2), a microcontroller (14) which evaluates the conductor-to-ground voltages (U_{L1-PE} U_{L2-PE}), a PFC controller (16) for each active conductor (L1, L2), the PFC controllers (16) being controlled by the microcontroller (14) according to balanced conductor-to-ground voltages (U_{L1-PE} U_{L2-PE}) as target values and reproducing a control impedance for each active conductor (L1, L2) in such a manner that a voltage balance is set between the active conductors (L1, L2), and comprising an intermediate circuit (18) which stores energy converted in the control impedances and a converter (20) which outputs the energy stored in the intermediate circuit (18) to the power supply system (2).

2. The balancing device (10) according to claim 1, wherein a data circuit (22) between the balancing device (10) and an insulation monitoring device (IMD), information on the set control impedances being transferred to the insulation monitoring device (IMD) on the data circuit (22).

3. An enhanced insulation monitoring device, including an integrated balancing device (10) according to claim 1 for forming a structural unit.

4. A method for balancing an ungrounded power supply system (2) having at least two active conductors (L1, L2), the method comprising the steps to be executed in a balancing device (10) switched multipolarly between the corresponding active conductors (L1, L2) and ground potential (PE):
detecting a corresponding conductor-to-ground voltage (U_{L1-PE} U_{L2-PE}) by means of a voltage measuring device (12), evaluating the conductor-to-ground voltages (U_{L1-PE} U_{L2-PE}) by means of a microcontroller (14), indicating balanced conductor-to-ground voltages (U_{L1-PE} U_{L2-PE}) as target values to each PFC controller (16) controlled by the microcontroller (14) for each conductor (L1, L2),
reproducing a control impedance by means of the corresponding PFC controller (16) for each active conductor (L1, L2) in such a manner that a voltage balance is set between the active conductors (L1, L2),
storing energy in an intermediate circuit (18), the energy having been converted in the control impedances, and
outputting the energy stored in the intermediate circuit (18) to the power supply system (2) by means of a converter (20).

5. The method according to claim 4, wherein transmission of information on the set control impedances to an insulation monitoring device (IMD) by means of a data circuit (22) between the balancing device (10) and the insulation monitoring device (IMD).

6. A method of testing the operability of an insulation monitoring device (IMD) using the balancing device (10) according to claim 1.

7. A method for generating common mode currents for fault location by means of insulation fault location systems in an ungrounded power supply system (2) using the balancing device (10) according to claim 1.
